(19) United States
(12) Patent Application Publication
(10) Pub. No.: US 2026/0082568 A1
(43) Pub. Date: Mar. 19, 2026

(54) SEMICONDUCTOR MEMORY AND METHOD FOR MANUFACTURING THE SAME

(71) Applicant: Shanghai Huali Integrated Circuit Corporation, Shanghai (CN)

(72) Inventors: Xing GAO, Shanghai (CN); Qin SUN, Shanghai (CN)

(73) Assignee: Shanghai Huali Integrated Circuit Corporation, Shanghai (CN)

(21) Appl. No.: 19/302,870

(22) Filed: Aug. 18, 2025

(30) Foreign Application Priority Data
Sep. 14, 2024 (CN) 202411298030.5

(51) Int. Cl. H10B 43/30; H10B 41/30; H10D 64/01; H10D 64/68

(52) U.S. Cl. CPC H10B 43/30; H10B 41/30; H10D 64/037; H10D 64/691; H10D 64/693

(57) ABSTRACT

The present application discloses a gate structure of the storage unit of semiconductor memory, comprising a first dielectric tunneling layer, a second dielectric storage layer, a third graded blocking layer, a high-k dielectric layer and a metal gate. The first dielectric tunneling layer is formed on the surface of the semiconductor substrate. The second dielectric storage layer is formed on top surface of the first dielectric tunneling layer. The third graded blocking layer is formed on top surface of the second dielectric storage layer. The third graded blocking layer comprises a body layer and a top layer. Based on the oxygen concentration of the body layer, oxygen concentration of top layer gradually increases in a direction from the bottom surface to top surface of top layer. The present application also discloses a method for manufacturing a semiconductor memory. The present application is capable of improving device reliability.

### CROSS-REFERENCES TO RELATED APPLICATIONS

This application claims priority to Chinese patent application No. CN202411298030.5, filed on Sep. 14, 2024, the disclosure of which is incorporated herein by reference in its entirety.

### TECHNICAL FIELD

The present application relates to technical field of semiconductor integrated circuit manufacturing, and in particular to a semiconductor memory. The present application further relates to a method for manufacturing semiconductor memory.

### BACKGROUND

As shown in FIG. 1, it is a schematic diagram of the structure of a storage unit of an existing SONOS memory. SONOS is abbreviation of silicon of silicon substrate 101, silicon oxide of silicon oxide tunneling layer 102, silicon nitride of silicon nitride storage layer 103, silicon oxide of the blocking layer 104 and silicon of the polysilicon gate 105 in FIG. 1. The tunneling layer 102, the silicon nitride storage layer 103, the blocking layer 104 as well as the polysilicon gate 105 together form a gate structure. A source area 106 and a drain area 107 are self-alignedly formed in the silicon substrate 101 at both sides of the gate structure.

SONOS memory technology shown in FIG. 1 has been developed for many years. The main problem it faces is reliability performance, including data retention and endurance. As the area of SONOS memory continues to shrink, reliability window continues to shrink as well, and the problems it faces continue to increase.

As the embedded memory technology enters advanced nodes, introduction of high-k (HK) dielectric materials as well as metal gate (MG) processes has become necessary in order to ensure process compatibility with logic units. As shown in FIG. 2, it is schematic diagram of the structure of the storage unit of the existing HKMG SONOS memory. HKMG SONOS means that based on existing silicon, silicon oxide, silicon nitride, silicon oxide and silicon of polysilicon gate, HK and MG are used to replace the silicon of polysilicon gate. In FIG. 2, the gate structure is formed on surface of the silicon substrate 201, and the gate structure includes silicon oxide tunneling layer 202, silicon nitride storage layer 203, silicon oxide blocking layer 204, HK layer 205 as well as metal gate 206. A source area 207 and a drain area 208 are self-aligned in the silicon substrate 101 on both sides of the gate structure.

As shown in FIG. 2, the introduction of the metal gate (MG) avoids the generation of electron/hole pairs during the erase operation, which otherwise occurs in the conventional polysilicon gate (POLY) structure shown in FIG. 1. As a result, the problem of back tunneling of electrons/holes in the SONOS device is also avoided, thereby improving saturation depth of erase threshold voltage (Vte). Compared with the existing SONOS memory shown in FIG. 1, Vte saturation depth of the existing HKMG SONOS memory shown in FIG. 2 is increased by more than 500 mv. However, as SONOS storage area continues to shrink, the reliability window urgently needs to be continuously improved.

### BRIEF SUMMARY

According to some embodiments in this application, a semiconductor memory is disclosed in this application, a gate structure of storage unit of the semiconductor memory comprising: a first dielectric tunneling layer, a second dielectric storage layer, a third graded blocking layer, a high-k dielectric layer as well as a metal gate, wherein
the first dielectric tunneling layer is formed on surface of semiconductor substrate;
the second dielectric storage layer is formed on the top surface of the first dielectric tunneling layer;
the third graded blocking layer is formed on top surface of second dielectric storage layer; the third graded blocking layer comprises a body layer and a top layer, and an oxygen concentration of the top layer gradually increases from bottom surface to top surface thereof, based on an oxygen concentration of the body layer.

In some cases, the material of the semiconductor substrate comprises silicon.

In some cases, the third graded blocking layer is subjected to plasma oxidation, and the top layer is located in the area oxidized by the plasma.

In some cases, material of the third graded blocking layer comprises silicon oxynitride.

In some cases, material of first dielectric tunneling layer comprises silicon oxide.

In some cases, material of second dielectric storage layer comprises silicon nitride.

In some cases, the material of the high-k dielectric layer comprises hafnium oxide; and material of the gate conductive material layer of the metal gate comprises Al.

According to some embodiments in this application, a method for manufacturing the semiconductor memory is disclosed, the step of forming gate structure of a memory unit comprises:
forming a first dielectric tunneling layer on surface of a semiconductor substrate;
forming a second dielectric storage layer on top surface of first dielectric tunneling layer;
forming a material layer of a third graded blocking layer on top surface of second dielectric storage layer;
performing a first oxidation process on top area of material layer of the third graded blocking layer to form the top layer, wherein a portion of material layer beneath the top layer serves as a body layer, and the third graded blocking layer is composed of the body layer and the top layer; based on an oxygen concentration of the body layer, the first oxidation process causes oxygen concentration of the top layer to gradually increase in a direction from bottom surface to top surface of the top layer;
forming a high-k dielectric layer on top surface of the third graded blocking layer; and
forming a metal gate on the top surface of the high-k dielectric layer.

In some cases, the material of the semiconductor substrate comprises silicon.

In some cases, the first oxidation process is performed by the plasma oxidation.

In some cases, material of the third graded blocking layer comprises silicon oxynitride.

In some cases, material of the first dielectric tunneling layer includes silicon oxide.

In some cases, material of second dielectric storage layer comprises silicon nitride.

In some cases, material of high-k dielectric layer comprises hafnium oxide, and wherein material of the gate conductive material layer of the metal gate comprises Al.

Unlike gate structure of conventional HKMG SONOS memory, the gate structure of the semiconductor memory according to the present application provides a specially configured blocking layer between the charge storage layer and the high-k dielectric layer. In the present application, the use of a metal gate during the erase operation of the memory unit prevents the generation of the electron-hole pairs that typically occurs in the SONOS memories employing the polysilicon gate, thereby avoiding the back injection of electrons or holes. As a result, the conventional blocking layer is omitted and replaced with graded blocking layer, referred to as the third graded blocking layer. In third graded blocking layer, the area with a higher oxygen concentration is provided only in the top layer, while the body layer retains the initial oxygen concentration of the material layer of the third graded blocking layer. Due to the absence of significant back injection of electrons or holes, oxygen concentration in top layer is sufficient to provide a barrier against direct electron tunneling. In addition, compared with conventional blocking layers formed of oxide layers, dielectric constant of the third graded blocking layer can be independently set from its blocking capability. As a result, a higher dielectric constant can be achieved, and electrical thickness of third graded blocking layer is reduced compared to the blocking layer of the conventional HKMG SONOS memory. For instance, when silicon oxynitride is used as third graded blocking layer, its electrical thickness is smaller than that of blocking layer using silicon oxide. The reduction in electrical thickness enhances coupling between the metal gate and the semiconductor substrate, thereby increasing the electric field across dielectric layers between metal gate and substrate, making it easier for electrons to be stored in deep energy levels of the second dielectric storage layer. This can improve both data retention and program/erase endurance. Therefore, the present application ultimately enhances device reliability, and the reliability window is significantly expanded.

### BRIEF DESCRIPTION OF THE DRAWINGS

The present application is further described in detail below with the reference to the accompanying drawings and specific embodiments:

FIG. 1 is a schematic diagram of the structure of storage unit of an existing SONOS memory;

FIG. 2 is a schematic diagram of the structure of storage unit of an existing HKMG SONOS memory;

FIG. 3 is a schematic diagram of the structure of storage unit of a semiconductor memory according to an embodiment of the present application;

FIG. 4 is an oxygen concentration distribution curve of top layer of the third graded blocking layer of memory unit of the semiconductor memory according to an embodiment of the present application;

FIG. 5A to 5C are schematic diagrams of device structures in steps of forming third graded blocking layer in the method for manufacturing semiconductor memory according to an embodiment of the present application;

FIG. 6 is a schematic diagram of the energy bands of storage unit of a conventional HKMG SONOS memory;

FIG. 7 is a schematic diagram of energy bands of memory unit of a semiconductor memory according to an embodiment of the present application.

### DETAILED DESCRIPTION OF THE DISCLOSURE

As shown in FIG. 3, it is a schematic diagram of the structure of the storage unit of semiconductor memory according to an embodiment of present application. The gate structure of the storage unit of the semiconductor memory according to the embodiment of the present application comprises: a first dielectric tunneling layer 302, a second dielectric storage layer 303, a third graded blocking layer 304, a high-k dielectric layer 305 and a metal gate 306.

The first dielectric tunneling layer 302 is formed on surface of the semiconductor substrate 301.

In the embodiment of the present application, material of the semiconductor substrate 301 comprises silicon.

The material of the first dielectric tunneling layer 302 comprises silicon oxide. The first dielectric tunneling layer 302 is usually formed by oxidizing the semiconductor substrate 301 and possesses good quality. The first dielectric tunneling layer 302 is thin and meets the requirement of direct charge tunneling, for example, the thickness is less than 5 nm.

The second dielectric storage layer 303 is formed on top surface of first dielectric tunneling layer 302.

In the embodiment of the present application, the second dielectric storage layer 303 is made of silicon nitride (Si₃N₄), which stores charge using trap energy levels of the silicon nitride.

The third graded blocking layer 304 is formed on top surface of second dielectric storage layer 303. The third graded blocking layer 304 comprises body layer 3041 as well as top layer 3042. Based on oxygen concentration of body layer 3041, the oxygen concentration of the top layer 3042 gradually increases in a direction from bottom surface to top surface of the top layer 3042.

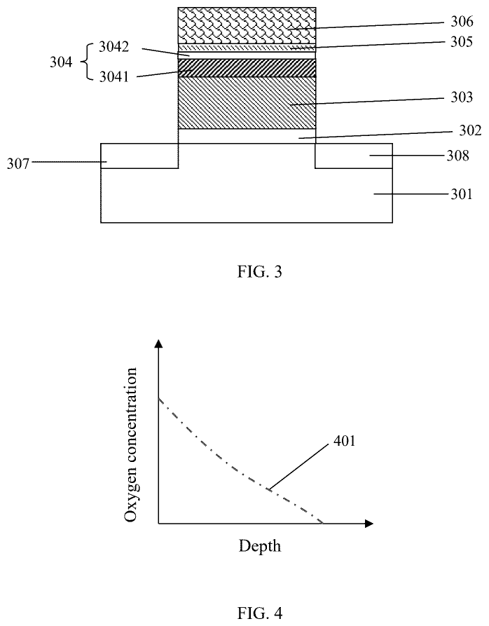

As shown in FIG. 4, it is an oxygen concentration distribution curve 401 of the top layer of third graded blocking layer of memory unit of the semiconductor memory according to an embodiment of the present application. The depth of the abscissa in FIG. 4 is the distance from the top surface of the top layer 3042.

In the embodiment of the present application, the third graded blocking layer 304 is oxidized by plasma, and the top layer 3042 is located in the area oxidized by plasma.

The material of the third graded blocking layer 304 comprises silicon oxynitride.

In the embodiment of the present application, high-k dielectric layer 305 is made of a material comprising hafnium oxide.

The gate conductive material layer of the metal gate 306 comprises Al.

The memory unit further comprises a source area 307 and a drain area 308 formed in semiconductor substrate 301 on both sides of the gate structure in a self-aligned manner.

As shown in FIG. 3, in the embodiment of the present application, the semiconductor substrate 301, the first dielectric tunneling layer 302, the second dielectric storage layer 303, the third graded blocking layer 304, the high-k dielectric layer 305 and the metal gate 306 can be referred to as a S—O—N—SiON-HK-M structure, wherein S represents silicon corresponding to the semiconductor substrate 301, O represents oxide layer corresponding to first dielectric tunneling layer 302, N represents silicon nitride corresponding to second dielectric storage layer 303, SiON represents SiON of third graded blocking layer 304, HK represents high-k dielectric layer 305 and M represents metal gate 306. Unlike conventional SONOS structure, it is a structure evolved from or derived based on the SONOS structure.

Unlike the gate structure of a conventional HKMG SONOS memory, gate structure of semiconductor memory according to the embodiments of the present application provides a specially configured blocking layer between the dielectric storage layer and high-k dielectric layer 305. In the embodiments of the present application, metal gate 306 prevents generation of electron-hole pairs during the erase operation of the memory unit, which typically occurs in SONOS memories with polysilicon gates, thereby avoiding the back injection of electrons or holes. Accordingly, the conventional blocking layer is eliminated and replaced with a graded blocking layer, i.e., the third graded barrier layer 304. In the third graded blocking layer 304, the area with a high oxygen concentration is only present in top layer 3042, while body layer 3041 retains the initial oxygen concentration of the material layer of the third graded blocking layer 304. As the back injection of electrons or holes is substantially eliminated, the oxygen concentration in the top layer 3042 is adequately set to inhibit the direct electron tunneling. In addition, compared with conventional structures employing an oxide layer as blocking layer, the dielectric constant of the third graded blocking layer 304 can be configured independently of its function, thereby enabling a higher dielectric constant to be achieved. As a result, the electrical thickness of the third graded blocking layer 304 can be reduced relative to that of blocking layer in existing HKMG SONOS memories. For example, when silicon oxynitride is used as material of third graded blocking layer 304, electrical thickness thereof is smaller than that of a silicon oxide blocking layer. The reduction in electrical thickness enhances the coupling effect between metal gate 306 and semiconductor substrate 301, and strengthens the electric field in the dielectric stack between the metal gate and the semiconductor substrate. This facilitates the injection of electrons into the deep energy levels of the second dielectric storage layer 303, thereby improving both data retention as well as program/erase endurance. Accordingly, the embodiment of present application can ultimately enhance device reliability, and significantly widen the reliability window.

In order to more intuitively understand technical effect brought by the third graded blocking layer 304 of memory unit of semiconductor memory according to the embodiment of the present application, further explanation is given below in conjunction with the energy band diagram:

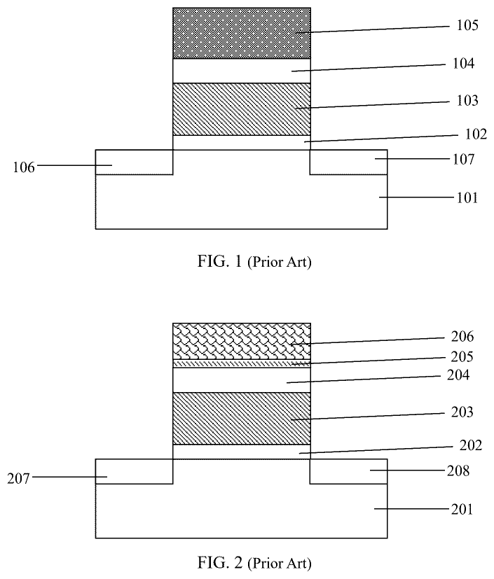

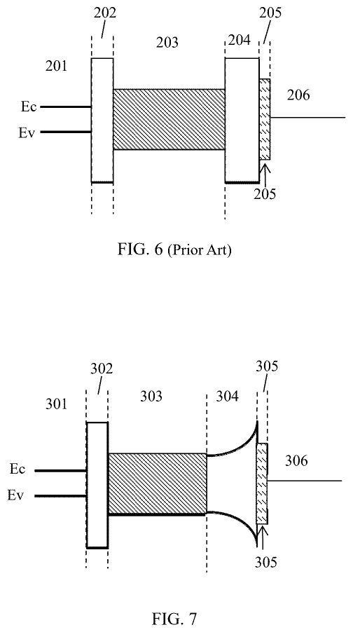

As shown in FIG. 6, it is a schematic diagram of the energy band of the storage unit of existing HKMG SONOS memory shown in FIG. 2. In FIG. 6, Ec represents the conductive bottom energy level, Ev represents the top energy level of valence band. FIG. 6 shows energy band structure of the corresponding silicon substrate 201, tunneling oxide layer 202, silicon nitride storage layer 203, silicon oxide blocking layer 204, high-k dielectric layer 205 as well as metal gate 206 in FIG. 2.

As shown in FIG. 7, a schematic energy band diagram of the memory unit of the semiconductor memory according to the embodiment of present application is illustrated. FIG. 7 shows energy band structures corresponding to semiconductor substrate 301, first dielectric tunneling layer 302, second dielectric storage layer 303, third graded blocking layer 304, the high-k dielectric layer 305 and metal gate 306, as depicted in FIG. 3. By comparing silicon oxide blocking layer 204 in FIG. 6 with third graded blocking layer 304 in FIG. 7, it can be observed that bandgap of silicon oxide blocking layer 204 remains constant across its entire thickness, corresponding to that of silicon oxide, which has relatively low dielectric constant. In contrast, in FIG. 7, the bandgap of the third graded blocking layer 304 gradually increases along with increase in oxygen concentration. Near the high-k dielectric layer 305, bandgap as well as the corresponding valence band maximum (Ev) and conduction band minimum (Ec) of the third graded blocking layer 304 become close to those of silicon oxide blocking layer 204 in FIG. 6. When using the metal gate 306, the increased bandgap near the interface with high-k dielectric layer 305 still effectively functions as a charge blocking layer. Importantly, a major portion of the third graded blocking layer 304 has a relatively smaller bandgap, which allows the material of third graded blocking layer 304 to be selected from materials having a higher dielectric constant, such as silicon oxynitride, thereby enabling reduction in equivalent oxide thickness (EOT).

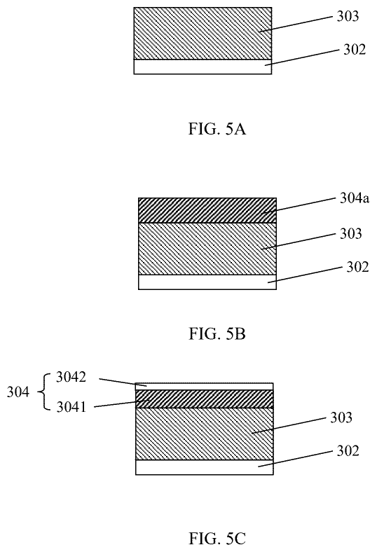

As shown in FIG. 5A to 5C, schematic cross-sectional views of device structures are provided to illustrate the steps of forming the third graded blocking layer in manufacturing method of a semiconductor memory according to an embodiment of the present application. In manufacturing method of semiconductor memory described herein, the process of forming the gate structure of a memory unit comprises the following steps:

As shown in FIG. 5A, a first dielectric tunneling layer 302 is formed on the surface of the semiconductor substrate 301. For the clarity, the internal structure of the semiconductor substrate 301 is omitted in FIG. 5A. Please refer to FIG. 3 for the detailed structure of the semiconductor substrate 301.

In the embodiment of the present application, the material of semiconductor substrate 301 comprises silicon.

The material of the first dielectric tunneling layer 302 comprises silicon oxide. The first dielectric tunneling layer 302 is usually formed by oxidizing the semiconductor substrate 301 and possesses good quality. The first dielectric tunneling layer 302 is thin and meets the requirement of direct charge tunneling, for example, the thickness is less than 5 nm.

As shown in FIG. 5A, the second dielectric storage layer 303 is formed on the top surface of the first dielectric tunneling layer 302.

As shown in FIG. 5B, material layer 304a of the third graded blocking layer 304 is formed on the top surface of the second dielectric storage layer 303.

In the embodiment of the present application, material layer 304a of the third graded blocking layer 304 is a silicon oxynitride layer.

As shown in FIG. 5C, the first oxidation process is performed on the top area of the material layer 304a of the third gradual blocking layer 304 to form a top layer 3042, and the material layer 304a of the third gradual blocking layer 304 at the bottom of the top layer 3042 serves as body layer 3041, and the third graded blocking layer 304 is composed of body layer 3041 and top layer 3042. Based on the oxygen concentration of the body layer 3041, the first oxidation process causes the oxygen concentration of the top layer 3042 to gradually increase in the direction from the bottom surface to the top surface of the top layer 3042.

In the embodiment of the present application, the first oxidation process is performed using plasma oxidation. Plasma oxidation may be implemented as low-temperature plasma oxidation (DPO).

As shown in FIG. 3, a high-k dielectric layer 305 is formed on the top surface of the third graded blocking layer 304.

In the embodiment of the present application, material of high-k dielectric layer 305 comprises hafnium oxide.

Metal gate 306 is formed on the top surface of the high-k dielectric layer 305.

In the embodiment of the present application, gate conductive material layer of metal gate 306 comprises Al.

The embodiment of the present application further comprises a patterning process for gate structure. In some embodiment, a polysilicon dummy gate is used in patterning process of the gate structure, and after the polysilicon dummy gate defines the formation area of the gate structure, metal gate 306 is used to replace polysilicon dummy gate, that is, a gate-last process is used.

After patterning process of the gate structure is completed, a source area 307 and a drain area 308 are formed in semiconductor substrate 301 on both sides of the gate structure by self-alignment.

The above description provides a detailed explanation of present application through specific embodiments, which are not intended to limit the scope of the present application in any way. Various modifications as well as improvements may be made by those skilled in the art without departing from spirit and scope of the present application, and such modifications and improvements shall also fall within the scope of protection of the present application.

What is claimed is:

1. A semiconductor memory, a gate structure of storage unit comprising a first dielectric tunneling layer, a second dielectric storage layer, a third graded blocking layer, a high-k dielectric layer as well as a metal gate, wherein
the first dielectric tunneling layer is formed on surface of semiconductor substrate;
the second dielectric storage layer is formed on top surface of first dielectric tunneling layer;
the third graded blocking layer is formed on top surface of second dielectric storage layer; the third graded blocking layer comprises a body layer and a top layer, and an oxygen concentration of the top layer gradually increases from bottom surface to top surface thereof, based on an oxygen concentration of the body layer.

2. The semiconductor memory according to claim 1, wherein material of the semiconductor substrate comprises silicon.

3. The semiconductor memory according to claim 1, wherein the third graded blocking layer is subjected to plasma oxidation, and the top layer is located in area oxidized by the plasma.

4. The semiconductor memory according to claim 3, wherein the material of the third graded blocking layer comprises silicon oxynitride.

5. The semiconductor memory according to claim 1, wherein material of the first dielectric tunneling layer comprises silicon oxide.

6. The semiconductor memory according to claim 1, wherein material of the second dielectric storage layer comprises silicon nitride.

7. The semiconductor memory according to claim 1, wherein material of the high-k dielectric layer comprises hafnium oxide; and the material of the gate conductive material layer of the metal gate comprises Al.

8. A method for manufacturing the semiconductor memory, wherein the step of forming gate structure of a memory unit comprises:
forming a first dielectric tunneling layer on surface of a semiconductor substrate;
forming a second dielectric storage layer on top surface of first dielectric tunneling layer;
forming a material layer of a third graded blocking layer on top surface of the second dielectric storage layer;
performing a first oxidation process on top area of material layer of the third graded blocking layer to form the top layer, wherein a portion of material layer beneath the top layer serves as a body layer, and the third graded blocking layer is composed of the body layer and the top layer; based on an oxygen concentration of the body layer, the first oxidation process causes oxygen concentration of the top layer to gradually increase in a direction from bottom surface to top surface of the top layer;
forming a high-k dielectric layer on the top surface of the third graded blocking layer; and
forming a metal gate on the top surface of the high-k dielectric layer.

9. The method for manufacturing semiconductor memory according to claim 8, wherein the material of the semiconductor substrate comprises silicon.

10. The method for manufacturing semiconductor memory according to claim 8, wherein the first oxidation process is performed by plasma oxidation.

11. The method for manufacturing semiconductor memory according to claim 10, wherein the material of the third graded blocking layer comprises silicon oxynitride.

12. The method for manufacturing semiconductor memory according to claim 8, wherein the material of the first dielectric tunneling layer comprises silicon oxide.

13. The method for manufacturing semiconductor memory according to claim 8, wherein the material of the second dielectric storage layer comprises silicon nitride.

14. The method for manufacturing semiconductor memory according to claim 8, wherein the material of the high-k dielectric layer comprises hafnium oxide, and wherein material of the gate conductive material layer of the metal gate comprises Al.
